(19) United States
(12) Patent Application Publication
(10) Pub. No.: US 2014/0170797 A1
(43) Pub. Date: Jun. 19, 2014

(54) SENSOR CHIP PROTECTIVE IMAGE SENSOR PACKAGING METHOD

(71) Applicant: STACK DEVICES CORP., Chunan Miaoli (TW)

(72) Inventors: Mon-Nan HO, Chunan Miaoli (TW); Chien-Heng LIN, Chunan Miaoli (TW); Ching-Shui CHENG, Chunan Miaoli (TW); Po-Wen CHOU, Chunan Miaoli (TW)

(73) Assignee: Stack Devices Corp., Chunan Miaoli (TW)

(21) Appl. No.: 13/717,107

(22) Filed: Dec. 17, 2012

(51) Int. Cl. H01L 31/18

(52) U.S. Cl. CPC H01L 31/18
USPC 438/65

(57) ABSTRACT

A sensor chip protective image sensor packaging method includes the steps of a) installing an image sensor chip in a circuit substrate and then covering a passivation layer on a sensing zone of the image sensor chip, b) using a plurality of lead wires to connect respective conducting contacts of the circuit substrate to respective conducting contacts of the image sensor chip, c) molding an encapsulation on the circuit substrate and the image sensor chip to wrap the lead wires, d) removing the passivation layer, and e) mounting a light transmissive cover in the encapsulation over the sensing zone of the image sensor chip. Thus, the passivation layer protects the sensing zone of the image sensor chip against contamination and damage prior before having been protected by the cover, and therefore, this image sensor chip packaging method has high-yield performance.

### BACKGROUND OF THE INVENTION

1. Field of the Invention

The present invention relates to image sensor packaging technology and more particularly, to a sensor chip protective image sensor packaging method for packaging image sensor package structures.

2. Description of the Related Art

Referring to FIG. 1, a conventional image sensor packaging method is known comprising the step of bonding a CCD (charge coupled device) or CMOS (complementary metal-oxide-semiconductor) image sensor chip 10 to a circuit substrate 11 and then soldering lead wires 12 to connect respective conducting contacts of the image sensor chip 10 to respective conducting contacts of the circuit substrate 11, and the step of molding an encapsulation 13 of a special packaging material on the circuit substrate 11 and the image sensor chip 10 using a compression molding technique and then bonding a glass plate 14 to the image sensor chip 10 over a sensing zone 15 of the image sensor chip 10. Thus, the lead wires 12 are embedded in the encapsulation 13 and will not break easily under the protection of the encapsulation 13. Further, the sensing zone 15 of the image sensor chip 10 is protected by the glass plate 14 and adapted to sense images outside the glass plate 14.

However, according to the aforesaid prior art image sensor packaging method, the sensing zone 15 of the image sensor chip 10 tends to be contaminated or damaged during the packaging process, affecting the quality of the image sensor and leading to low yield.

### SUMMARY OF THE INVENTION

The present invention has been accomplished under the circumstances in view. It is one object of the present invention to provide a sensor chip protective image sensor packaging method for packaging image sensor package structures, which protects the sensing zone of the image sensor chip against contamination and damage during the packaging process, achieving high-yield performance.

To achieve this and other objects of the present invention, a sensor chip protective image sensor packaging method comprises the steps of: a) installing an image sensor chip in a circuit substrate and then covering a passivation layer on a sensing zone of the image sensor chip, b) using a plurality of lead wires to connect respective conducting contacts of the circuit substrate to respective conducting contacts of the image sensor chip, c) molding an encapsulation on the circuit substrate and the image sensor chip to wrap the lead wires, d) removing the passivation layer, and e) mounting a light transmissive cover in the encapsulation over the sensing zone of the image sensor chip.

Other advantages and features of the present invention will be fully understood by reference to the following specification in conjunction with the accompanying drawings, in which like reference signs denote like components of structure.

### BRIEF DESCRIPTION OF THE DRAWING

FIG. 1 is a schematic drawing illustrating an image sensor chip package structure made according to the prior art.

FIG. 2 is schematic drawing illustrating the packaging process of a sensor chip protective image sensor packaging method in accordance with a first embodiment of the present invention (I).

FIG. 3 is schematic drawing illustrating the packaging process of a sensor chip protective image sensor packaging method in accordance with the first embodiment of the present invention (II).

FIG. 4 is schematic drawing illustrating the packaging process of a sensor chip protective image sensor packaging method in accordance with the first embodiment of the present invention (III).

FIG. 5 is schematic drawing illustrating the packaging process of a sensor chip protective image sensor packaging method in accordance with the first embodiment of the present invention (IV).

FIG. 6 is schematic drawing illustrating the packaging process of a sensor chip protective image sensor packaging method in accordance with the first embodiment of the present invention (V).

FIG. 7 is schematic drawing illustrating the packaging process of a sensor chip protective image sensor packaging method in accordance with the first embodiment of the present invention (VI).

FIG. 8 is schematic drawing illustrating an alternate form of the packaging process of a sensor chip protective image sensor packaging method in accordance with the first embodiment of the present invention.

FIG. 9 is schematic drawing illustrating an image sensor package structure fabricated by a sensor chip protective image sensor packaging method in accordance with a second embodiment of the present invention.

FIG. 10 is schematic drawing illustrating an image sensor package structure fabricated by a sensor chip protective image sensor packaging method in accordance with a third embodiment of the present invention.

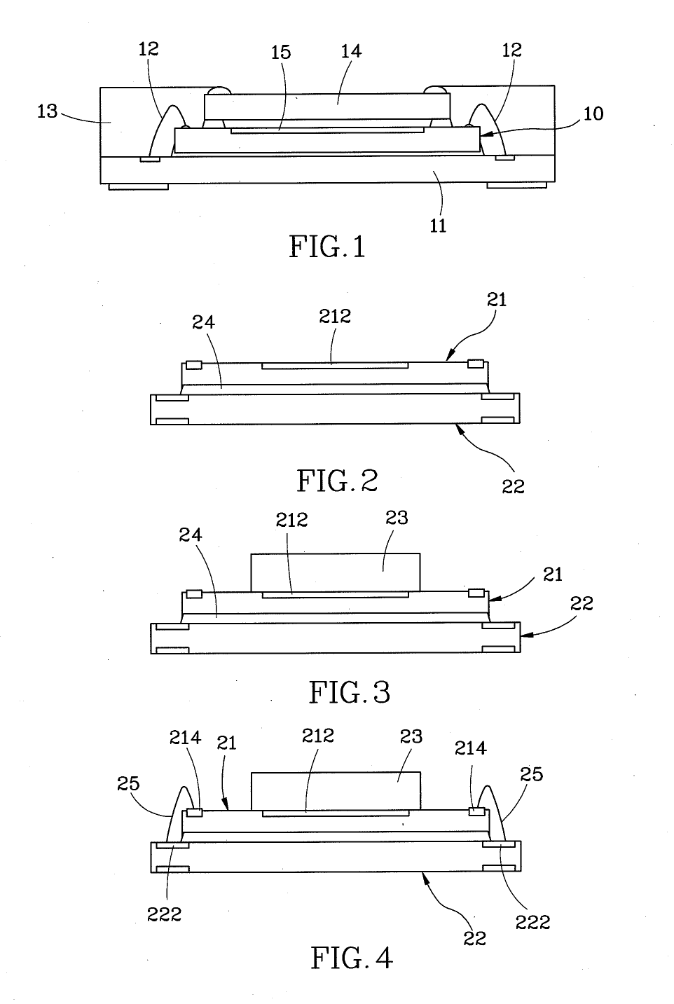

### DETAILED DESCRIPTION OF THE PREFERRED EMBODIMENT

Before describing the present invention, it is to be understood that like reference numerals throughout the drawings denote like component parts.

Referring to FIGS. 2-7, a sensor chip protective image sensor packaging method in accordance with a first embodiment of the present invention is to package an image sensor package structure 20 (see FIG. 7). This sensor chip protective image sensor packaging method comprises the steps outlined hereinafter.

a) As shown in FIGS. 2 and 3, install an image sensor chip 21 in a circuit substrate 22 and then cover a protective layer 23 over a sensing zone 212 of the image sensor chip 21.

The passivation layer on the sensing zone 212 of the image sensor chip 21 is a thin layer of a special liquid material (for example, acrylic acid) printed or transfer-printed on the image sensor chip. By means of printing or transfer-printing technology, the passivation layer can be quickly coated on the sensing zone 212 of the image sensor chip 21, facilitating mass production.

In this embodiment, the image sensor chip 21 is bonded to the circuit substrate 22 with an adhesive 24, and then the passivation layer 23 is covered on the sensing zone 212. Further, the covering area of the passivation layer 23 is greater than the area of the sensing zone 212 but smaller than the area of the image sensor chip 21. However, as an alternate form of this embodiment, the image sensor chip 21 can be installed in the circuit substrate 22 after the passivation layer 23 has been covered on the sensing zone 212, and the area of the passivation layer 23 can be equal to the area of the image sensor chip 21.

b) As shown in FIG. 4, use a plurality of lead wires 25 to connect respective conducting contacts 222 at the circuit substrate 22 and respective conducting contacts 214 at the image sensor chip 21.

There is no limitation to the amount of the lead wires 25. The amount of the lead wires 25 can be determined subject to actual requirements. This step is same as the prior art technique. However, the arrangement of the passivation layer 23 can protect the sensing zone 212 of the image sensor chip 21 against contamination or damage during step a).

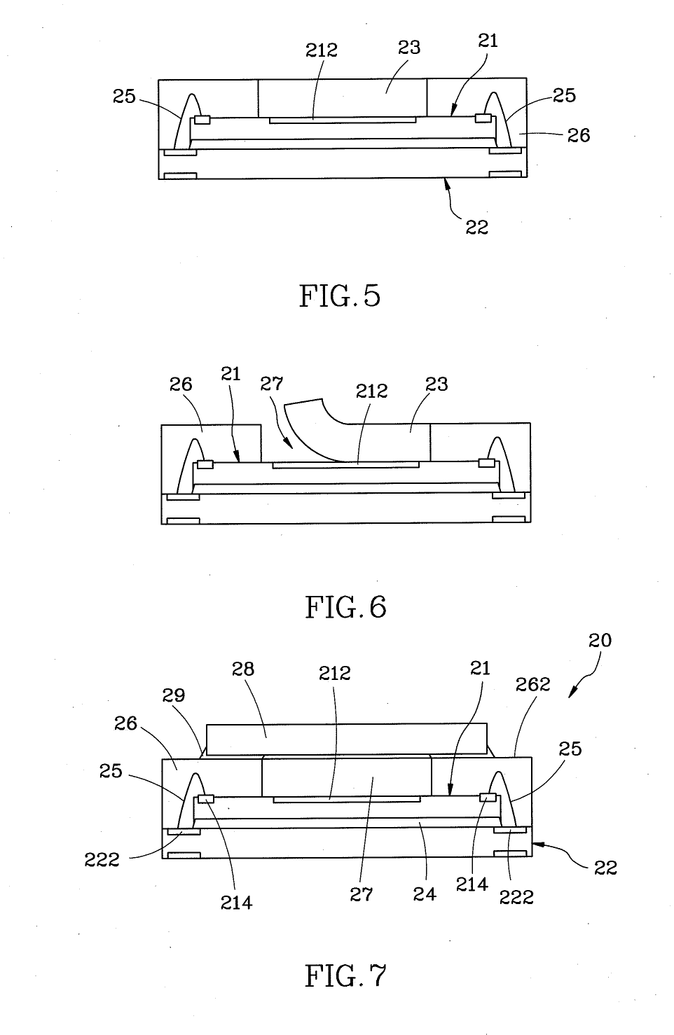

c) As shown in FIG. 5, mold an encapsulation 26 on the circuit substrate 22 and the image sensor chip 21 to wrap the lead wires 25.

The encapsulation 26 is formed of a special packaging material using a compression molding technique, and adapted to protect the lead wires 25, avoiding lead wire breaking. The passivation layer 23 can also protect the sensing zone 212 of the image sensor chip 21 against contamination or damage during step c). Further, in this embodiment, the encapsulation 26 and the passivation layer 23 have the same height. Thus, the passivation layer 23 provides a buffer effect during compression molding of the encapsulation 26. However, the passivation layer 23 can also provide a buffer effect if it is higher than the encapsulation 26.

d) As shown in FIG. 6, remove the passivation layer 23. After removal of the passivation layer 23, a sensing space 27 is formed at the center of the encapsulation 26 above the sensing zone 212 of the image sensor chip 21.

e) As shown in FIG. 7, mount a light transmissive cover 28 in the encapsulation 26 over the sensing zone 212 of the image sensor chip 21.

In this embodiment, the cover 28 is a glass plate of excellent light transmission bonded to a top wall 262 of the encapsulation 26 with an adhesive 29.

Thus, the sensing zone 212 of the image sensor chip 21 is protected by the cover 28 and can sense images outside the cover 28.

In the aforesaid image sensor chip packaging method, the passivation layer 23 protects the sensing zone 212 of the image sensor chip 23 against contamination or damage during step b) and step c) prior to the installation of the cover 28. Therefore, this image sensor chip packaging method has high-yield performance.

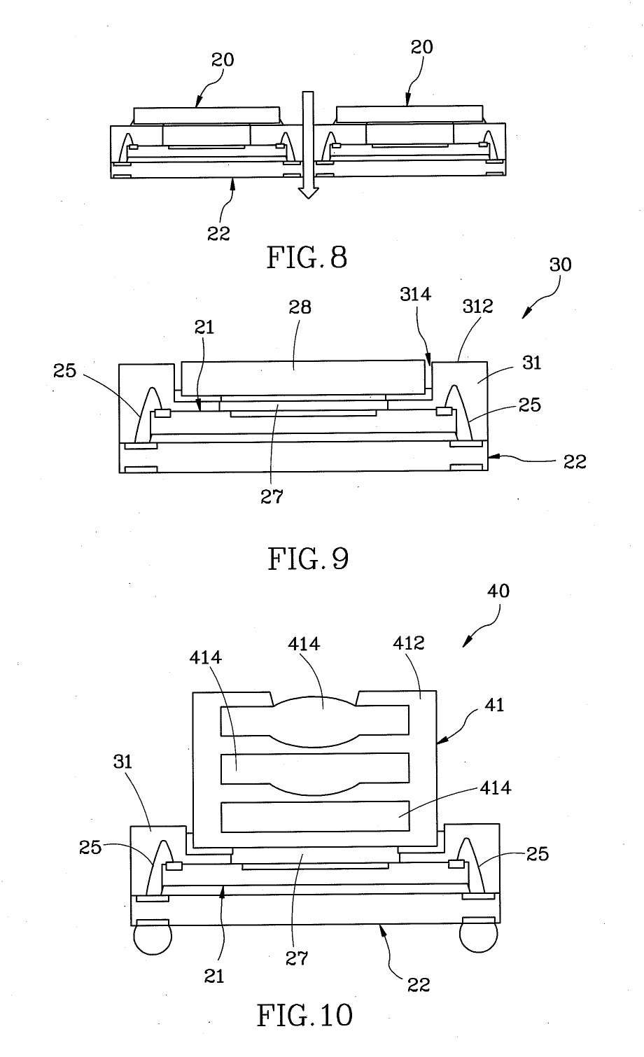

It's worth mentioning that in actual application, the image sensor chip packaging method of the present invention is to produce a plurality of package structures 20 using one common said circuit substrate 22 at a time, and these package structures 20 are separated using a cutting technique (see FIG. 8). However, this cutting technique can be performed prior to step d), avoiding contamination of the sensing zone 212 of the image sensor chip 21 during cutting.

Referring to FIG. 9, an image sensor package structure 30 made in accordance with a second embodiment of the present invention is shown. When compared to the image sensor package structure 20 made in accordance with the first embodiment of the present invention, the encapsulation 31 of this image sensor package structure 30 includes a recess 314 located at the top wall 312 thereof, and the cover 28 is mounted in the recess 314. Thus, the thickness of the image sensor package structure 30 in accordance with this second embodiment of the present invention is thinner than the thickness of the image sensor package structure 20 in accordance with the first embodiment of the present invention. This low profile image sensor package structure 30 is suitable for use in a camera, cell phone, notebook computer and other low profile electronic devices.

Referring to FIG. 10, an image sensor package structure 40 made in accordance with a third embodiment of the present invention is shown. The image sensor package structure 40 made in accordance with this third embodiment is substantially similar to the image sensor package structure 30 made in accordance with the aforesaid second embodiment with the exception that the cover 41 of the image sensor package structure 40 is a camera lens assembly comprising a lens barrel 412 and a plurality of lenses 414 mounted in the lens barrel 412. Thus, when the image sensor package structure 40 is mounted in a mobile electronic device, such as camera, cell phone, notebook computer or the like, the mobile electronic device provides an image sensor chip and a camera lens assembly, and no further camera lens means is necessary

In actual application, the cover installed in the image sensor chip package during step e) is not limited to a glass plate or camera lens assembly. The cover can be made of any other suitable material or structure that admits light and allows the sensing zone of the image sensor chip to sense images outside the cover.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A sensor chip protective image sensor packaging method, comprising:
a) installing an image sensor chip in a circuit substrate and then covering a passivation layer on a sensing zone of said image sensor chip;
b) using a plurality of lead wires to connect respective conducting contacts of said circuit substrate to respective conducting contacts of said image sensor chip;
c) molding an encapsulation on said circuit substrate and said image sensor chip to wrap said lead wires;
d) removing said passivation layer; and
e) mounting a light transmissive cover in said encapsulation over said sensing zone of said image sensor chip.

2. The sensor chip protective image sensor packaging method as claimed in claim 1, wherein the area of said passivation layer is larger than the area of said sensing zone and smaller or equal to the area of said image sensor chip.

3. The sensor chip protective image sensor packaging method as claimed in claim 1, wherein during step c), said encapsulation is kept equal to or lower than the elevation of said passivation layer.

4. The sensor chip protective image sensor packaging method as claimed in claim 1, wherein said light transmissive cover is mounted at a top wall of said encapsulation.

5. The sensor chip protective image sensor packaging method as claimed in claim 1, wherein said encapsulation comprises a top wall and a recess at said top wall; said light transmissive cover is mounted in said recess.

6. The sensor chip protective image sensor packaging method as claimed in claim 1, wherein said light transmissive cover is a glass plate.

7. The sensor chip protective image sensor packaging method as claimed in claim 1, wherein said light transmissive cover is a camera lens means.
